(19) United States
(12) Patent Application Publication
(10) Pub. No.: US 2008/0042681 A1
(43) Pub. Date: Feb. 21, 2008

(54) Integrated circuit device with current measurement

(75) Inventor: Martin Kerber, Muenchen (DE)

Correspondence Address: DAVIDSON, DAVIDSON & KAPPEL, LLC, 485 SEVENTH AVENUE, 14TH FLOOR, NEW YORK, NY, 10018, US

(73) Assignee: Infineon Technologies AG, Muenchen (DE)

(21) Appl. No.: 11/502,924

(22) Filed: Aug. 11, 2006

(51) Int. Cl. G01R 31/26

(52) U.S. Cl. 324/765

(57) ABSTRACT

An integrated circuit device includes a plurality of transistors having gate dielectrics forming logic for the integrated circuit device, a voltage supply line connected to the transistors, and a current measurement device determining when the current in the voltage supply line exceeds a threshold.

### BACKGROUND OF THE INVENTION

The present invention relates to integrated circuit devices and to detection of device failures.

Various tests for the reliability of dielectric materials are known. Time dependent dielectric breakdown (TDDB) tests for example are often run at the wafer level to estimate a time to failure for dielectric materials used in integrated circuit products.

### BRIEF DESCRIPTION OF THE SEVERAL VIEWS OF THE DRAWING(S)

The present invention will be further described with reference to a preferred embodiment, in which:

FIG. 1 shows schematically one embodiment of an integrated circuit device with an alarm for indicating an increased power consumption; and

FIG. 2 shows schematically the integrated circuit device in chip form.

### DETAILED DESCRIPTION OF THE INVENTION

The present invention provides an integrated circuit device comprising: a plurality of transistors having gate dielectrics forming logic for the integrated circuit device; a voltage supply line connected to the transistors; and a current measurement device determining when the current in the voltage supply line exceeds a threshold.

The present invention also provides a method for detecting soft dielectric breakdown in an integrated circuit product comprising the steps of: monitoring the current in a power supply line of the integrated circuit product in a section of the integrated circuit product; and determining that soft dielectric breakdown is occurring when the current in the power supply line increases.

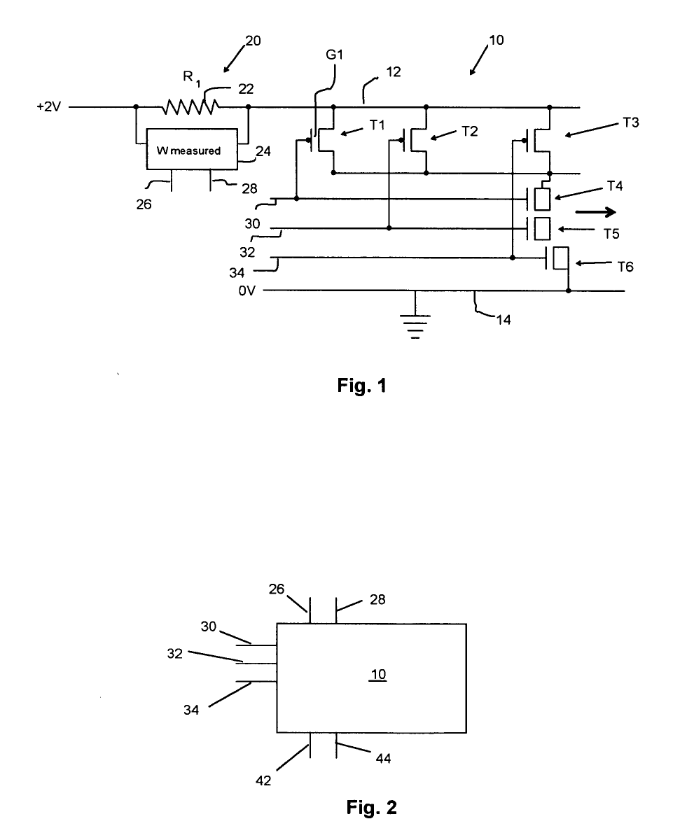

FIG. 1 shows schematically an integrated circuit device 10 having a plurality of transistors T1, T2, T3, T4, T5, T6 etc. between a power supply line 12 and a ground line 14. The device may have hundreds or thousands of transistors supplied with power from one or more power supply lines 12, which form the logic for the integrated circuit device. A plurality of logic inputs 30, 32, 34, etc. may be provided.

The integrated circuit device 10 has a current measurement device 20, which can include a resistor 22 in the power supply line 12, and a voltage measurement device 24.

The current measurement device 20 however may be of any type, for example that disclosed in U.S. Pat. No. 6,995,555, hereby incorporated by reference herein. If used with a resistor in the power supply line 12, the voltage measurement device 24 may be for example similar to one disclosed in U.S. Pat. No. 7,034,559, also incorporated by reference herein.

Dielectric material for the gate oxides of the transistors, such as the gate oxide for gate G1 of transistor T1, can suffer from dielectric breakdown. When using thick gate dielectrics or gate voltages which exceed 3.5V, for example, the gate oxide failure typically leads to a low resistive shunt, or so-called hard breakdown. This can prevent functioning of the entire device.

However, smaller gate voltages can lead to dielectric breakdowns which do not necessarily result in the malfunction of the product. Rather supply current is increased due to the gate leakage and also due to the fact that the following logic node does not have the entire supply voltage, and thus may cause a limited by-pass current in the following stage. This increases power consumption but does not cause catastrophic failure, and is generally referred to as soft breakdown. The degradation amount also depends on the operating voltage and the substrate temperature of the chip.

The current measurement device 20 of the present invention thus can measure the supply current in supply line 20 in the chip or a section of the chip, and raise a flag detectable at an output 28 when the supply current exceeds a specific trigger level. The trigger level can be set to a constant beforehand, or can be a value set at a final test of the product and stored in a non-volatile memory or ROM via an input 26.

During a function test in the product using the integrated circuit device 10, which may be an individual chip, the flag can be detected to indicate that power consumption has increased and that the integrated circuit device 10 may fail in the near future. This is so because as the gate dielectric breaks down for a few of the transistors, it is likely that it will also be breaking down for more transistors in the near future. The more and more breakdown events occur, the probability for catastrophic failure increases. When thin gate dielectrics, often high-K dielectrics, approaching 1 nanometer are used, the spread in time of the breakdown events can be quite wide. So that considerable time elapses from the first breakdown event up to a number which leads to a noticeable increase of the supply current.

The flag at output 28 may for example simply be a binary value. The function test may be provided by an extra pin at the product using the integrated circuit device and simply determine the value. Software can then be provided to submit a warning that the power consumption of the integrated circuit has increased, which is a strong indicator of upcoming failure. Such a warning prevents or reduces the probability of catastrophic failure and allows timely replacement of the endangered part.

For example only, the device 10 may operate at 2V and draw 0.5 amp of current. A resistor 22 may be provided which during normal operating conditions causes a voltage drop of 50 mV, in other words a resistor with a fixed resistance of 100 mOhms.

The voltage measurement device 24 may be set, for example via pin 26 and a ROM, to have a threshold of 75 mV. However, pin 26 is may be eliminated and the threshold set via the manufactured configuration of the device 24.

During operation, when voltage measurement device 24 reaches a voltage drop of 75 mV, the flag at output 28 is changed from zero to one.

This flag then can be used to indicate during a test query of the product incorporating device 10 that soft dielectric breakdown is occurring.

An example of the voltage drop when the device is in its new operating condition is 50 to 100 mV, and the supply current level threshold for causing the flag can be at a current increase of 1.5 to 2 times the new operating current.

The operating current may be tested in the new state of the integrated circuit, for example, prior to shipment, and the pin 28 used to set the current level threshold individually for each integrated circuit product. However, similar determined values may also be used for a plurality of simiintegrated integrated circuit devices.

FIG. 2 shows the integrated circuit product 20 scheically as a single chip, with pins 26, 28, and device input pins 30, 32, 34 and power supply pin 42 for connection to line 12 and ground pin 44 for connection to ground line 14.

1. An integrated circuit device comprising:
a plurality of transistors having gate dielectrics, the transistors forming logic for the integrated circuit device;
a voltage supply line connected to the transistors; and
a current measurement device determining when the current in the voltage supply line exceeds a threshold.

2. The integrated circuit device as recited in claim 1 wherein the current measurement device includes a resistor in the voltage supply line and a voltage measurement device.

3. The integrated circuit device as recited in claim 2 wherein a voltage drop across the resistor when the integrated circuit device is new is 50 to 100 mV.

4. The integrated circuit device as recited in claim 3 wherein the threshold is set to a value equal to or between 1.5 and 2.0 times a current when the integrated circuit device is new.

5. The integrated circuit device as recited in claim 1 wherein the threshold is set to a value equal to or between 1.5 and 2.0 times a current when the integrated circuit device is new.

6. The integrated circuit device as recited in claim 1 wherein the current measurement device includes a flag set when the threshold is exceeded.

7. A single chip comprising the integrated circuit device as recited in claim 1.

8-11. (canceled)

12. The integrated circuit device as recited in claim 1 wherein a number of the plurality of transistors forming the logic is at least three.

13. The integrated circuit device as recited in claim 1 wherein the voltage supply line is connected to at least three of the plurality of transistors.

14. A method for detecting soft dielectric breakdown in an integrated circuit device as recited in claim 1 comprising the steps of:
monitoring the current in the voltage supply line; and
determining that soft dielectric breakdown is occurring when the current in the voltage supply line increases.

15. The method as recited in claim 14 wherein the determining occurs when the current exceeds a preset threshold.

16. The method as recited in claim 14 further comprising setting a flag upon determination of the soft dielectric breakdown.

17. The method as recited in claim 16 further comprising detecting the flag during a test routine of a product incorporating the integrated circuit device.
